(19) United States
(12) Patent Application Publication
(10) Pub. No.: US 2025/0175128 A1
(43) Pub. Date: May 29, 2025

(54) POWER AMPLIFIER

(71) Applicant: Mitsubishi Electric Corporation, Tokyo (JP)

(72) Inventors: Kazuya YAMAMOTO, Tokyo (JP); Satoshi SUZUKI, Tokyo (JP); Katsuya KATO, Tokyo (JP)

(73) Assignee: Mitsubishi Electric Corporation, Tokyo (JP)

(21) Appl. No.: 18/839,863

(22) PCT Filed: Aug. 8, 2022
(86) PCT No.: PCT/JP2022/030255

§ 371 Date: Aug. 20, 2024

(51) Int. Cl. H03F 1/32; H03F 1/02; H03F 3/24

(52) U.S. Cl. CPC H03F 1/3276; H03F 1/0288; H03F 3/245; H03F 2200/211; H03F 2200/435

(57) ABSTRACT

An amplifier (Trc,Trp) uses a GaN HEMT. A diode linearizer (LNZ) and a variable attenuator (VATT) are connected in series to an input of the amplifier (Trc, Trp). A peak detector (DET) detects a peak value of a drain voltage of the amplifier (Trc,Trp). A controller (CTL) makes the diode linearizer (LNZ) function as a linearizer to reduce an attenuation amount of the variable attenuator (VATT) if the peak value exceeds a threshold.

### FIELD

The present disclosure relates to a power amplifier.

### BACKGROUND

High-output operation and high-linearity operation are required of a power amplifier for a cellular base station in, e.g., the 4th generation mobile communication system (4G) and the 5th generation mobile communication system (5G) in order to deliver a less distorted radio wave, i.e., a signal with a low error rate at the time of reception over a long distance. Also, high-efficiency operation is strongly required for reduction in power consumption of the base station itself.

To respond to the above-described requirements, a Doherty amplifier capable of high-efficiency operation even at average output power lower by 7 to 9 dB than peak output power is adopted as a current power amplifier for a cellular base station. The Doherty amplifier can significantly improve efficiency at the time of backoff operation as compared with a general single-chain amplifier. However, linearity of an output signal with respect to an input signal, i.e., how linear input-output relationships in amplitude and phase characteristics are deteriorates. For this reason, a Digital Pre-distorter (DPD) is placed in front of an amplifier, and the inverse of a component which is to be distorted by the amplifier is input to the amplifier in advance, thereby performing amplification operation while compensating for linearity deterioration. The compensation is made while output signals from the amplifier are sequentially monitored via a coupler (directional coupler). To give an appropriate amplitude and phase to an inverse component to be input to an amplifier, the DPD is provided with an analog attenuator, an analog phase shifter, or a function equivalent thereto as needed in addition to a digital signal processing function and a digital/analog conversion function.

Si-LDMOSs have been the mainstream as transistors used in power amplifiers for base stations. However, along with practical use of GaN HEMTs, GaN HEMTs which are operable at a power supply voltage of 40 to 50 V higher than 28 V for LDMOSs and are more capable of high-efficiency operation are starting to be applied. Many GaN HEMTs are applied especially to Doherty power amplifiers for 5G base stations in the 3 to 4 GHz band higher in frequency than a band of frequencies not more than 2 GHZ (see, e.g., PTL 1).

A GaN Doherty power amplifier has a strong memory effect arising from trapping in a GaN HEMT and suffers the problem of a current amplification state changing depending on a past amplification state. It is well known that, for example, if low power is amplified immediately after high power is amplified, a gain or a phase changes.

To suppress distortion in a signal in consideration of the above-described memory effect, a DPD for a base station makes distortion compensation in consideration of the memory effect. However, product development frequently experiences a case example where distortion compensation does not work well even with use of the DPD. Examples of the case example include a case where an input-output amplitude characteristic (AM-AM) and phase characteristic (AM-PM) of a Doherty power amplifier change rapidly within a given output power range or the amounts of change are large. For this reason, a circuit is designed such that DPD compensation works well, the amounts of change fall within predetermined ranges, and such that changes are slow.

The inventors experienced, in design and evaluation of a Doherty power amplifier, a defective condition where a DPD worked as designed in a large part of a desired frequency band but did not work well in the vicinity of an end of the band.

Various analyses have showed that the cause is a memory effect arising from a momentary drain voltage of a GaN HEMT. A case where a DPD does not make distortion compensation well is a case where the amounts of change in input-output amplitude characteristic (AM-AM) and phase characteristic (AM-PM) fall outside compensation ranges, as described earlier. The amount of compensation for a change in phase characteristic is tightly restricted. For this reason, if a phase characteristic changes greatly, it is effective to implement a phase change suppression function in a power amplifier to suppress a phase change and keep the phase change within a compensation range for a DPD (see, e.g., PTL 1).

A diode linearizer is suited to implement the above-described function in a power amplifier at a low price. Since a diode linearizer can gently change a pass amplitude and phase in accordance with input power by a diode linearizer, the diode linearizer can suppress amplitude and phase changes.

### CITATION LIST

### Patent Literature

[PTL 1] JP 2001-103100 A

### SUMMARY

### Technical Problem

However, since a pass loss is different in principle of operation between a case where a diode linearizer functions and a case where the diode linearizer does not function, an actual gain of a power amplifier changes. This causes the problem of increase of a difference in actual gain of a power amplifier product.

The present disclosure has been made to solve the above-described problem, and has as its object to obtain a power amplifier capable of reducing a gain variation.

### Solution to Problem

A power amplifier according to the present disclosure includes: an amplifier using a GaN HEMT; a diode linearizer and a variable attenuator which are connected in series to an input of the amplifier; a peak detector detecting a peak value of a drain voltage of the amplifier; and a controller making the diode linearizer function as a linearizer to reduce an attenuation amount of the variable attenuator if the peak value exceeds a threshold.

### Advantageous Effects of Invention

In the present disclosure, a diode linearizer and a variable attenuator are connected in series to the input of an amplifier, and if a peak value of a drain voltage of the amplifier exceeds a threshold, the diode linearizer is made to function. For this reason, even if a digital pre-distorter cannot make distortion compensation well due to a memory effect arising from a momentary drain voltage of the amplifier, the linearizer can suppress deterioration of linearity. Thus, a distortion characteristic which is generally required of a base station can be achieved by distortion compensation by the digital pre-distorter. If the diode linearizer functions, since a gain decreases, an attenuation amount of the variable attenuator is reduced. This allows reduction in gain variation of a power amplifier.

### BRIEF DESCRIPTION OF THE DRAWINGS

FIG. 1 is a circuit diagram showing a power amplifier according to a first embodiment.

FIG. 2 is a circuit diagram showing a linearizer.

FIG. 3 is a graph showing AM-AM/AM-PM characteristics of a diode linearizer when the diode linearizer functions as a linearizer.

FIG. 4 is a graph showing AM-AM/AM-PM characteristics of a diode linearizer when the diode linearizer does not function as a linearizer.

FIG. 5 is a circuit diagram showing a variable attenuator.

FIG. 6 is a graph showing an example of an RF characteristic of a variable attenuator.

FIG. 7 is a circuit diagram showing a peak detector.

FIG. 8 is a circuit diagram showing a controller.

FIG. 9 is a graph showing examples of characteristics of a peak detector and a controller.

FIG. 10 is a graph showing an example of a characteristic of a controller.

FIG. 11 is a graph showing an example of a characteristic of a controller.

FIG. 12 is a graph showing output examples of the voltages Vo2a and Vo2b.

FIG. 13 is a circuit diagram showing a power amplifier according to the comparative example.

FIG. 14 is a chart showing a signal constellation for 64-QAM (64-quadrature modulation) used in 4G.

FIG. 15 is a chart showing a signal constellation for 256-QAM (256-quadrature modulation).

FIG. 16 is a graph showing respective time waveforms of 12 subcarriers with 15 kHz frequency spacing which form the basis of OFDM (orthogonal frequency-division multiplexing) in 4G.

FIG. 17 is a graph showing an example of a synthesized waveform of 12 subcarriers.

FIG. 18 is a graph showing an example of AM-AM/AM-PM characteristics of the power amplifier according to the comparative example in the absence of a problem.

FIG. 19 is a graph showing an example of AM-AM/AM-PM characteristics of the power amplifier according to the comparative example in the absence of a problem.

FIG. 20 is a graph showing an example of AM-AM/AM-PM characteristics of the power amplifier according to the comparative example in the presence of a problem.

FIG. 21 is a graph showing an example of AM-AM/AM-PM characteristics of the power amplifier according to the comparative example in the presence of a problem.

FIG. 22 is a graph showing a result of simulating an AM-AM shift amount with respect to a peak value of a drain voltage of a single GaN HEMT.

FIG. 23 is a graph showing a result of simulating an AM-PM shift amount with respect to the peak value of the drain voltage of the single GaN HEMT.

FIG. 24 is a diagram showing an example of a setup for measuring a transient response delay of a drain current after application of a stress voltage pulse.

FIG. 25 is a graph showing a drain voltage waveform at the time of stress voltage pulse application.

FIG. 26 is a graph showing a transient response waveform of the drain current corresponding to FIG. 25.

FIG. 27 is a chart for explaining influence of placing a linearizer in front on AM-AM/AM-PM.

FIG. 28 is a chart showing a gain in the absence of the variable attenuator.

FIG. 29 is a chart showing a gain in the presence of the variable attenuator.

FIG. 30 is a circuit diagram showing a power amplifier according to a second embodiment.

FIG. 31 is a circuit diagram showing a power amplifier according to a third embodiment.

FIG. 32 is a circuit diagram showing a power amplifier according to a fourth embodiment.

### DESCRIPTION OF EMBODIMENTS

A power amplifier according to the embodiments of the present disclosure will be described with reference to the drawings. The same components will be denoted by the same symbols, and the repeated description thereof may be omitted.

### First Embodiment

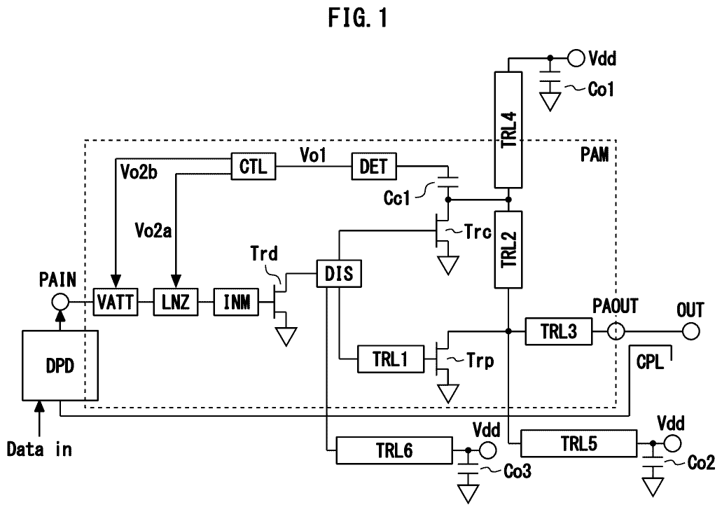

FIG. 1 is a circuit diagram showing a power amplifier according to a first embodiment. A power amplifier module PAM is a GaN HEMT Doherty power amplifier module which is mainly applied to a cellular base station. Linearity of an output signal with respect to an input signal of the power amplifier module PAM is distorted. For this reason, a Digital Pre-distorter DPD which performs distortion compensation operation is connected to an input terminal PAIN of the power amplifier module PAM. A directional coupler CPL is connected to an output terminal PAOUT of the power amplifier module PAM. The Digital Pre-distorter DPD monitors an output signal from the power amplifier module PAM with the directional coupler CPL and inputs the inverse of a component which is to be distorted by an amplifier of the power amplifier module PAM to the power amplifier module PAM in advance. In this manner, amplification operation is performed while deterioration of linearity is compensated for.

In the power amplifier module PAM, a carrier amplifier Trc and a peak amplifier Trp which are connected in parallel to each other constitute a Doherty amplifier. A driver amplifier Trd is connected to the input of the Doherty amplifier. GaN HEMTs are used as the carrier amplifier Trc, the peak amplifier Trp, and the driver amplifier Trd.

An input matching unit INM is connected to a gate of the driver amplifier Trd. A power division unit DIS divides an output signal from the driver amplifier Trd and inputs respective divided output signals to a gate of the carrier amplifier Tre and a gate of the peak amplifier Trp. The power division unit DIS also functions as an interstage matching unit.

A line TRL1 is connected between the power division unit DIS and the gate of the peak amplifier Trp. A line TRL2 is connected between a drain of the carrier amplifier Trc and a drain of the peak amplifier Trp. A line TRL3 is connected between the drain of the peak amplifier Trp and the output terminal PAOUT. A line TRL4 is connected between the drain of the carrier amplifier Trc and a power supply terminal Vdd. A capacitance Col is shunt-connected to a junction point of the line TRL4 and the power supply terminal Vdd. A line TRL5 is connected between the drain of the peak amplifier Trp and the power supply terminal Vdd. A capacitance Co2 is shunt-connected to a junction point of the line TRL5 and the power supply terminal Vdd. A line TRL6 is connected between the drain of the driver amplifier Trd and the power supply terminal Vdd. A capacitance Co3 is shunt-connected to a junction point of the line TRL6 and the power supply terminal Vdd. The lines TRLI to TRL6 change a phase by 90° to convert impedance. For example, the line TRL3 converts a result of power synthesis of an output signal from the carrier amplifier Tre and an output signal from the peak amplifier Trp into an output impedance of 50 Ω.

The line TRL4 is a feeder line which applies a phase rotation of 90° with respect to a fundamental frequency fo. The capacitances Co are bypass capacitances for sufficiently reducing impedance of the power supply terminal Vdd in the vicinity of the fundamental frequency fo and making nearly a short circuit. For this reason, impedance from the drain of the carrier amplifier Trc with a feeder line in view is sufficiently high in the vicinity of the fundamental frequency fo. Thus, a feeder line is designed not to have influence in terms of a high frequency downstream from the drain of the carrier amplifier Trc. The same applies to feeder lines for the peak amplifier Trp and the driver amplifier Trd.

Drain voltages of the carrier amplifier Trc, the peak amplifier Trp, and the driver amplifier Trd pulse at the fundamental frequency fo, and an average value of each drain voltage is a power supply voltage. Note that a momentary voltage is determined by load impedance of a transistor and varies greatly from a lowest value of about 0.5 to 2 V to a highest value about 2 to 2.5 times the power supply voltage. A coupling capacitance Cc1 monitors the drain voltage of the carrier amplifier Trc. A peak detector DET detects a peak value of the drain voltage of the carrier amplifier Trc that is monitored by the coupling capacitance Cc1.

A diode linearizer LNZ and a variable attenuator VATT are connected in series between the input terminal PAIN and the input matching unit INM. A controller CTL generates voltages Vo2a and Vo2b in accordance with an output voltage Vo1 of the peak detector DET and provides the voltages Vo2a and Vo2b to the diode linearizer LNZ and the variable attenuator VATT, respectively.

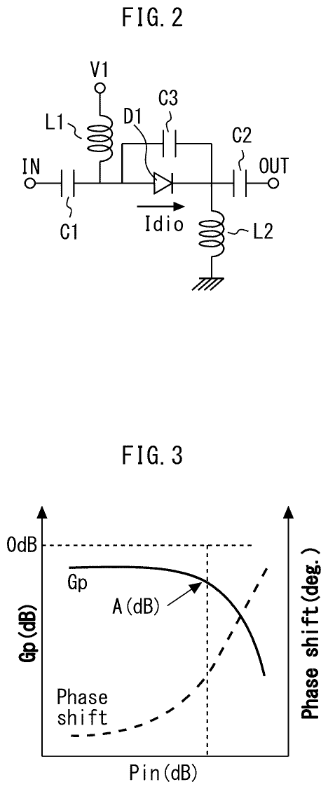

FIG. 2 is a circuit diagram showing a linearizer. The diode linearizer LNZ is a series diode linearizer in which a diode D1 is provided in series in an RF signal path. A capacitance C1 is connected to an anode of the diode D1, and a capacitance C2 is connected to a cathode. A capacitance C3 is connected in parallel to the diode D1. The anode of the diode D1 is connected to a terminal V1 via an inductor L1. The cathode of the diode D1 is grounded via an inductor L2. The voltage Vo2a is applied to the terminal V1 of the diode linearizer LNZ.

FIG. 3 is a graph showing AM-AM/AM-PM characteristics of a diode linearizer when the diode linearizer functions as a linearizer. If a current Idio which flows to the diode D1 is small (e.g., 3 mA), a gain Gp decreases with increase in input power Pin, and a phase advances positively. For this reason, a gain and a phase of a signal which passes through the diode linearizer LNZ change near the desired Pin. Thus, the diode linearizer LNZ functions as a linearizer near the desired Pin.

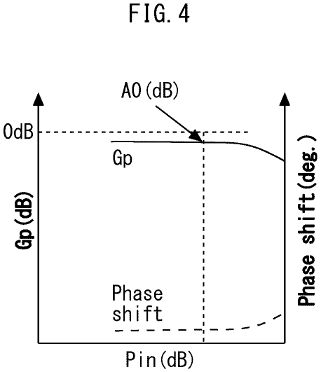

FIG. 4 is a graph showing AM-AM/AM-PM characteristics of a diode linearizer when the diode linearizer does not function as a linearizer. If the current Idio that flows to the diode D1 is large (e.g., 10 mA), a gain and a phase of a signal which passes through the diode linearizer LNZ do not change near the desired Pin. Thus, the diode linearizer LNZ does not function as a linearizer near the desired Pin.

If the voltage Vo2a is high, and a large amount of current flows to the diode D1, an input power level at which the diode linearizer LNZ functions as a linearizer rises. To make the diode linearizer LNZ function as a linearizer within a desired input power range, the voltage Vo2a is set to Vo2aL that is low to allow an appropriate amount of current to flow to the diode D1. Note that, since the current Idio does not flow unless the voltage exceeds a Schottky barrier Vbi (0.7 to 0.8 V) of the diode D1, Vo2aL is set to satisfy Vo2aL>Vbi. If the voltage Vo2a is Vo2aH that is high, a large current flows to the diode D1 to disable a function as a linearizer. The gain Gp is lower if the diode linearizer functions as a linearizer and is higher if the diode linearizer does not function as a linearizer. Note that, since the gain Gp of the amplifier is affected by an insertion loss by an amount corresponding to an on resistance of the diode D1 even if the diode linearizer LNZ does not function, the gain Gp of the amplifier decreases slightly as compared with a case without the diode linearizer LNZ.

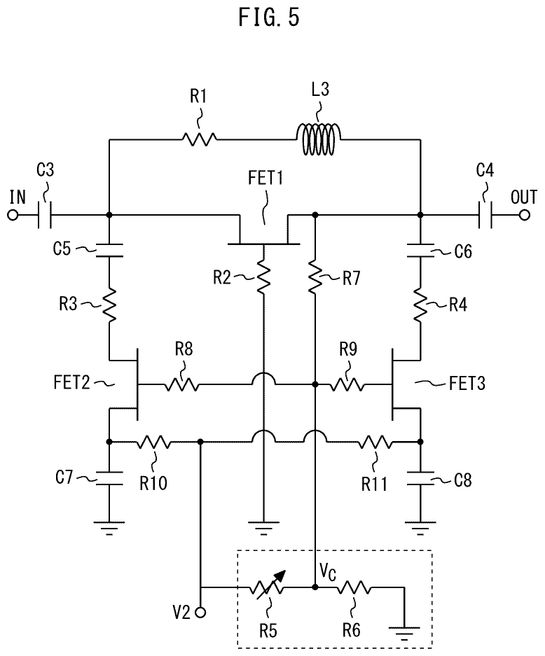

FIG. 5 is a circuit diagram showing a variable attenuator. The variable attenuator VATT is a π FET attenuator. A drain of a transistor FET1 is connected to an input terminal IN via a capacitance C3, and a source is connected to an output terminal OUT via a capacitance C4. A resistor R1 and an inductor L3 are connected in parallel to the source and the drain of the transistor FET1. A gate of the transistor FET1 is grounded via a resistor R2. The drain of the transistor FET1 is connected to a drain of a transistor FET2 via a capacitance C5 and a resistor R3. The source of the transistor FET1 is connected to a drain of a transistor FET3 via a capacitance C6 and a resistor R4. A source of the transistor FET2 is grounded via a capacitance C7. A source of the transistor FET3 is grounded via a capacitance C8. The voltage Vo2b is applied to a terminal V2 and is resistively divided by a variable resistor R5 and a resistor R6 to generate a voltage Vc. The voltage Vc is applied to the source of the transistor FET1 via a resistor R7, is applied to a gate of the transistor FET2 via a resistor R8, and is applied to a gate of the transistor FET3 via a resistor R9. The terminal V2 is connected to the source of the transistor FET2 via a resistor R10 and is connected to the source of the transistor FET3 via a resistor R11.

When the voltage Vo2b is 0 V, the voltage Vc is also 0 V. In this case, a gate-source voltage of FET1 becomes 0 V. Assuming that thresholds for FET1, FET2, and FET3 are −2 V, FET1 is turned on. Most RF signals pass through FET1 without passing through the resistor R1, and an insertion loss is caused only an ON resistance between the drain and the source of FET1 and is small. Gate-source voltages of FET2 and FET3 become 0 V to completely turn on FET2 and FET3. Thus, a x attenuator composed of the resistors R1, R2, and R3 is constructed in an equivalent sense.

The voltage Vc increases in a positive direction with increase in the voltage Vo2b. In this case, since a source potential of FET1 increases in the positive direction, the gate-source voltage increases in a negative direction. Since a channel resistance between the drain and the source of FET1 increases, FET1 approaches an off state. In this case, many RF signals pass through the resistor R1 to increase attenuation. An attenuation amount becomes the highest, e.g., about 14 dB, when the voltage Vo2b is a given positive voltage.

If a voltage division ratio between the variable resistor R5 and the resistor R6 is set to 1:1 when the voltage Vo2b is +6 V, the voltage Vc becomes +3 V. Since a gate voltage of FET1 is fixed at 0 V, the gate-source voltage of FET1 becomes −3 V to turn off FET1. The gate-source voltages of FET2 and FET3 become −3 V to turn off FET2 and FET3. Thus, power which leaks to GND via the resistors R3 and R4 is minimized.

As described above, an attenuation amount of the variable attenuator VATT is changed in accordance with the magnitude of the voltage Vo2b. Specifically, an attenuation amount of an RF signal which passes through the variable attenuator VATT increases with increase in the voltage Vo2b.

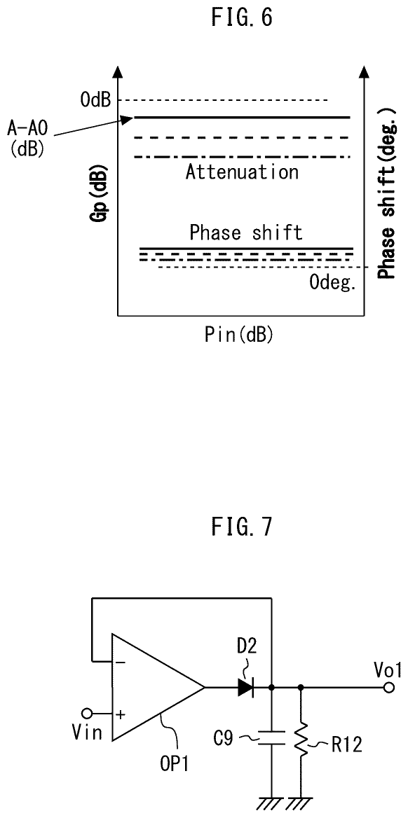

FIG. 6 is a graph showing an example of an RF characteristic of a variable attenuator. It is evident that an attenuation amount and a phase change are generally kept constant in the variable attenuator VATT regardless of increase in the input power Pin. Note that, since a signal is affected by a series resistance of a series FET at the time of passage through the FET even when the variable attenuator VATT is not activated, an insertion loss of about 0.2 to 0.3 dB is produced.

FIG. 7 is a circuit diagram showing a peak detector. The peak detector DET is an RC circuit which has a time constant which is appropriately set to fit a time constant for a modulation wave. A drain voltage Vin is input to a +terminal of an operational amplifier OP1. An output voltage Vo1 is output from the operational amplifier OP1 via a diode D2. The output voltage is also input to a-terminal of the operational amplifier OP1. A capacitance C9 and a resistor R12 are shunt-connected to the output of the operational amplifier OP1. With this configuration, the peak detector DET holds a peak value of the drain voltage. Note that a source follower may be used instead of the operational amplifier OP1. A source follower is preferable especially at a high frequency.

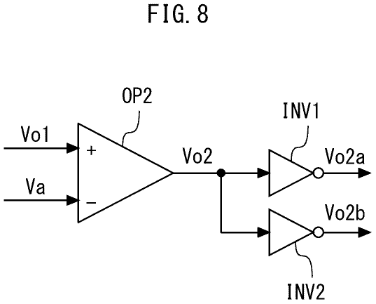

FIG. 8 is a circuit diagram showing a controller. In the controller CTL, an operational amplifier OP2 compares the output voltage Vo1 of the peak detector DET with a predetermined threshold Va to generate an output voltage Vo2. An inverter INV1 inverts the output voltage Vo2 to generate the voltage Vo2a and supplies the voltage Vo2a to the diode linearizer LNZ. An inverter INV2 inverts the voltage Vo2 to generate the voltage Vo2b and supplies the voltage Vo2b to the variable attenuator VATT. Since voltage levels desired by the diode linearizer LNZ and the variable attenuator VATT are often different, the inverter INV1 and the inverter INV2 level-shifts the voltage Vo2 to appropriate voltage levels to generate the voltages Vo2a and Vo2b. The voltages Vo2a and Vo2b are binary, high or low.

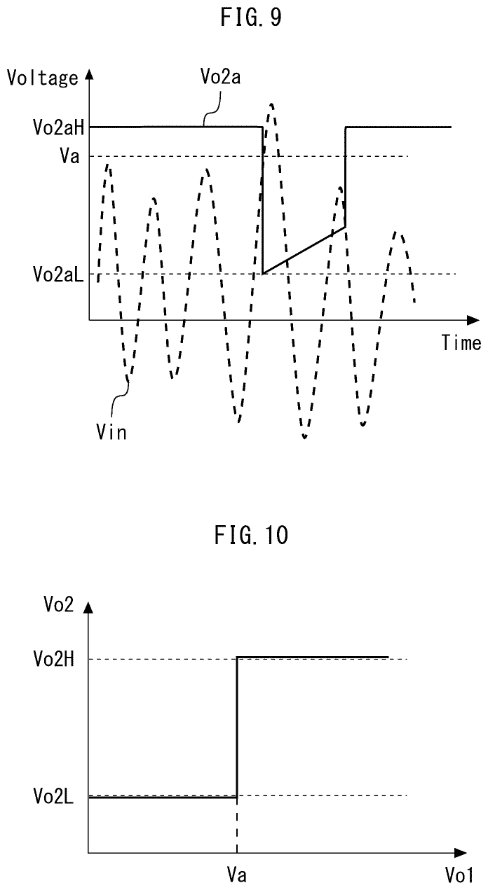

FIG. 9 is a graph showing examples of characteristics of a peak detector and a controller. If the voltage Vo1 (the drain voltage Vin) is higher than the threshold Va, the voltage Vo2a obtained by inverting the voltage Vo2 becomes Vo2aL that is low. If the voltage Vo1 (the drain voltage Vin) is lower than the threshold Va, the voltage Vo2a becomes Vo2aH that is high. Thus, a case where a peak value of the drain voltage is too high can be extracted by setting the threshold Va to an appropriate value.

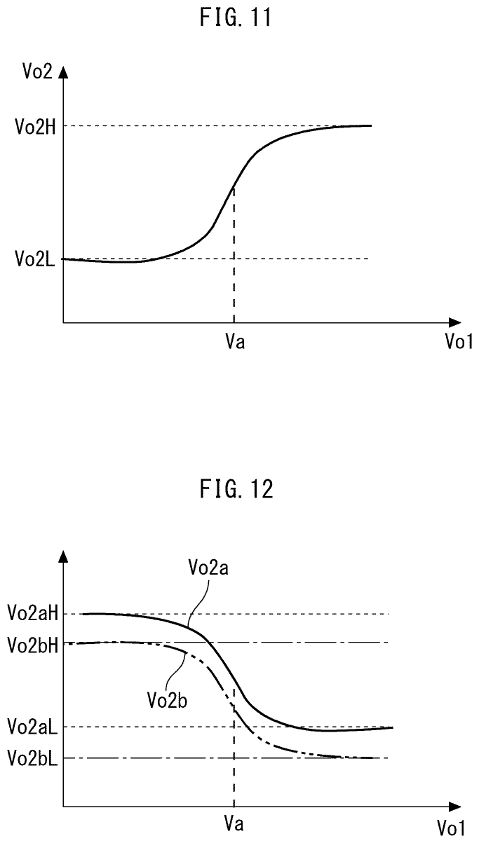

FIGS. 10 and 11 are graphs showing examples of a characteristic of a controller. FIG. 10 is a case where the output voltage Vo2 switches abruptly between high and low when Vo1 changes with respect to the threshold Va. FIG. 11 is a case where the output voltage Vo2 changes gently. A modulation signal increases or decreases fairly rapidly in the several to 100 MHz range, as will be described later. To avoid abrupt operation of the variable attenuator VATT and the diode linearizer LNZ and maintain continuity of a signal response, a relatively gentle response is suitable as a change in Vo2.

FIG. 12 is a graph showing output examples of the voltages Vo2a and Vo2b. If the voltage Vo1 is lower than the threshold Va, the voltages Vo2a and Vo2b become Vo2aH and Vo2bH at high levels. If the voltage Vo1 is higher than the threshold Va, the voltages Vo2a and Vo2b become Vo2aL and Vo2bL at low levels.

When the voltage Vo2a is low, an insertion loss of the diode linearizer LNZ increases. Since the voltage Vo2b is low, the attenuation amount of the variable attenuator VATT decreases. On the other hand, when the voltage Vo2a is high, the insertion loss of the diode linearizer LNZ decreases. Since the voltage Vo2b is high, the attenuation amount of the variable attenuator VATT increases. That is, if the peak value of the drain voltage of the carrier amplifier Trc exceeds the threshold Va, the controller CTL makes the diode linearizer LNZ function as a linearizer to reduce the attenuation amount of the variable attenuator VATT. On the other hand, if the peak value of the drain voltage of the carrier amplifier Trc falls below the threshold Va, the controller CTL does not make the diode linearizer LNZ function as a linearizer to increase the attenuation amount of the variable attenuator VATT.

Assume that an insertion loss of the diode linearizer LNZ at the desired Pin when the diode linearizer LNZ functions as a linearizer is A (dB) and that an insertion loss when the diode linearizer LNZ does not function as a linearizer is A0 (dB). For simplicity, a minimum attenuation amount of the variable attenuator VATT is assumed to be 0 dB. When the diode linearizer LNZ does not function as a linearizer, the attenuation amount of the variable attenuator VATT may be set to |A-A0| (dB). Note that A and A0 have negative values in dB.

As described above, the controller CTL controls the diode linearizer LNZ so as to change a gain and a phase of a signal which passes through the diode linearizer LNZ if the peak value of the drain voltage exceeds the threshold and so as not to change a gain and a phase of a signal which passes through the diode linearizer LNZ if the peak value of the drain voltage does not exceed the threshold. The controller CTL also controls the variable attenuator VATT such that an attenuation amount of a signal which passes through the variable attenuator VATT if the peak value of the drain voltage exceeds the threshold is smaller than an attenuation amount of a signal which passes through the variable attenuator VATT if the peak value of the drain voltage does not exceed the threshold.

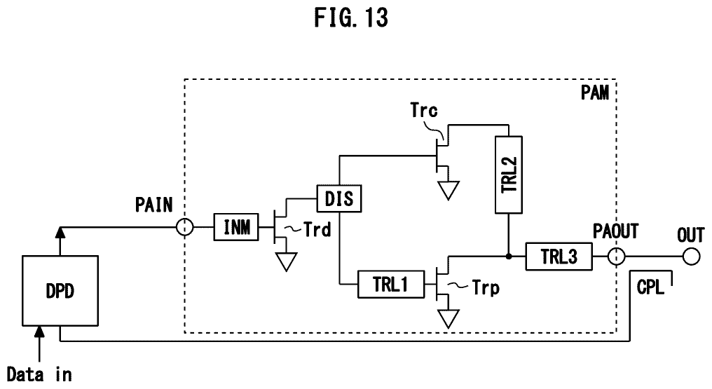

Effects of the present embodiment will be described in comparison with a comparative example. FIG. 13 is a circuit diagram showing a power amplifier according to the comparative example. The comparative example has no coupling capacitance Cc1, no peak detector DET, no controller CTL, no diode linearizer LNZ, and no variable attenuator VATT as compared with the first embodiment.

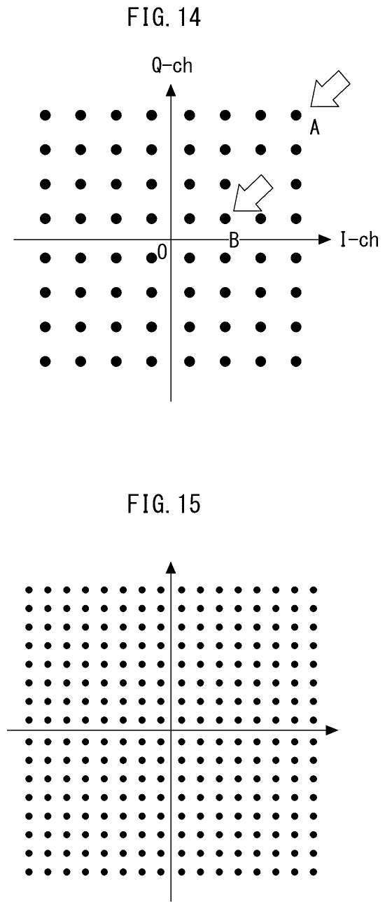

In 4G and 5G, if a modulation bandwidth is 20 MHz, the number of subcarriers is 12×100=1200. Since 64 is 2⁶, 6 bits can be sent by one subcarrier at one time. 1200 units×6 bits=7.2 kbits. One subcarrier sends 14000 symbols per second, and 7.2 k×14000=about 100 Mbits/sec can be sent in the 20 MHz band. FIG. 14 is a chart showing a signal constellation for 64-QAM (64-quadrature modulation) used in 4G. FIG. 15 is a chart showing a signal constellation for 256-QAM (256-quadrature modulation). An amplitude and a phase of a carrier wave are simultaneously changed such that the amplitude and the phase of the carrier wave are located at a dot in each figure, and information is placed on the carrier wave.

In 64-QAM, an amplitude changes from ±1 to ±3 to ±5 to ±7 from a center O in a direction of the I-ch, and changes in a direction of the Q-ch in the same manner. For example, a value A indicates a modulated value with an amplitude of sqrt(7\hat{ }2+7\hat{ }2)=sqrt(49*2)=sqrt (2)·7and a phase of 45°. A value B indicates a modulated value with an amplitude of sqrt (3\hat{ }2+1\hat{ }2)=sqrt(10) and a phase of about 18°. Note that since the I-ch and the Q-ch are the same with cosine and sine, an amplitude of a cosine carrier is set to +7, and an amplitude of a sine carrier is set to +7 to obtain a value of A (+7·cos (ωt)-(+7).sin (107 t)). Similarly, an amplitude of a cosine carrier may be set to 3, and an amplitude of a sine carrier may be set to 1 to obtain a value of B (+3·.cos (ωt)-(+1)·sin (ωt)). Such modulation is individually performed on 12 subcarriers.

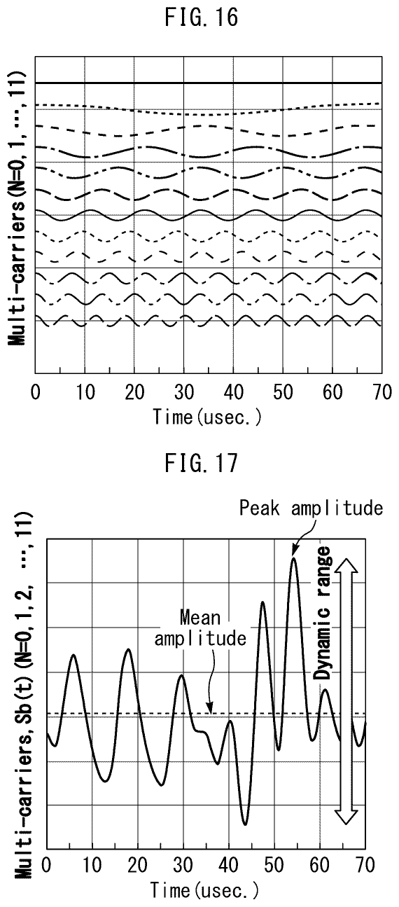

FIG. 16 is a graph showing respective time waveforms of 12 subcarriers with 15 kHz frequency spacing which form the basis of OFDM (orthogonal frequency-division multiplexing) in 4G. FIG. 17 is a graph showing an example of a synthesized waveform of 12 subcarriers. Modulations shown in FIGS. 14 and 15 are applied to each of the subcarriers in FIG. 16. The number of subcarriers for practical use is 1024 for a modulation bandwidth of 20 MHz in 4G. Thus, a difference between a peak value and an average value of the signal waveform shown in FIG. 17 is very large and is generally as large as 8 to 10 dB. A dynamic range which is a difference between a maximum value and a minimum value included in a signal is close to 30 dB.

To accurately demodulate 1024 subcarriers modulated by 64-QAM or 256-QAM as described above, it is necessary to accurately transmit the amplitudes and the phases shown in FIGS. 14 and 15 by radio. An amplifier is thus required to have extremely high linearity, i.e., to linearly amplify an input amplitude and phase over a wide range.

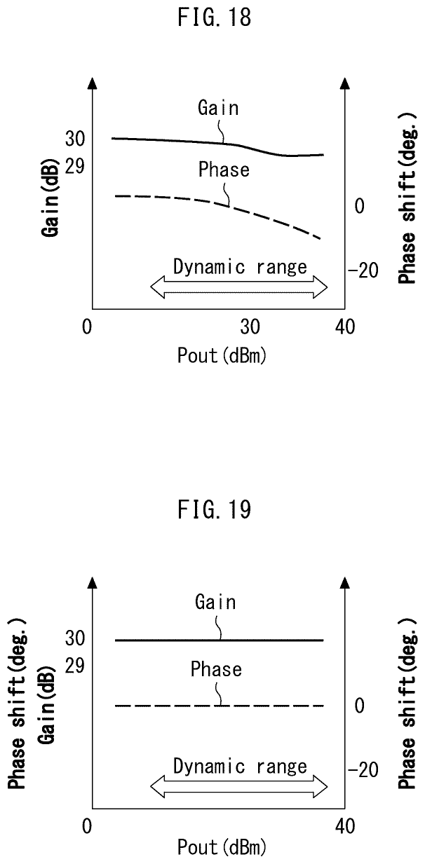

An example of AM-AM/AM-PM characteristics when a modulation signal as described above is input to the power amplifier according to the comparative example will be described. FIGS. 18 and 19 are graphs showing examples of AM-AM/AM-PM characteristics of the power amplifier according to the comparative example in the absence of a problem. Distortion compensation by a Digital Pre-distorter DPD is not made in FIG. 18, and distortion compensation is made in FIG. 19. It can be understood that, if distortion compensation by the Digital Pre-distorter DPD is appropriately made, the AM-AM/AM-PM characteristics exhibit flat linear operation over a wide dynamic range.

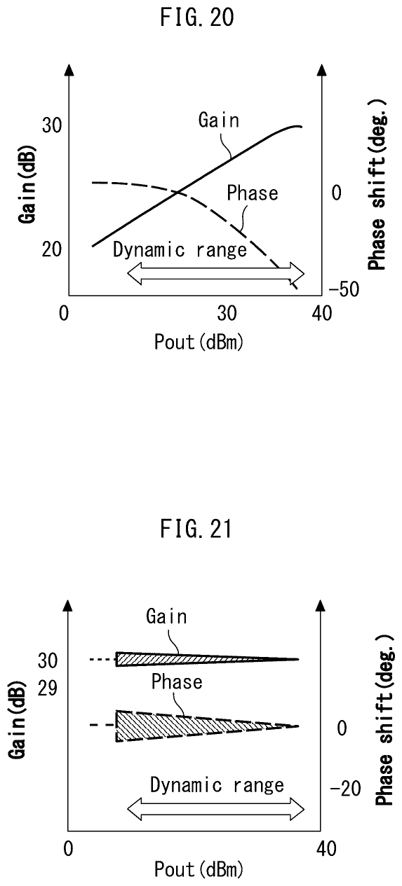

A defective condition experienced by the inventors will be described. FIGS. 20 and 21 are graphs showing examples of AM-AM/AM-PM characteristics of the power amplifier according to the comparative example in the presence of a problem. Distortion compensation by the Digital Pre-distorter DPD is not made in FIG. 20, and distortion compensation is made in FIG. 21. In FIG. 20, an AM-AM is a fairly steeply upward-sloping characteristic, and the amount of change in AM-PM is very large as compared with FIG. 18. For this reason, the power amplifier has not the linear ones shown in FIG. 19 but AM-AM/AM-PM characteristics having widths of given magnitudes as shown in FIG. 21, after distortion compensation. It is thus evident that distortion compensation by the Digital Pre-distorter DPD is not appropriately made.

The above-described defective condition is sometimes experienced if a change in gain is sharp, and the amount of change is large or if a phase change is large as in FIG. 20. Although distortion compensation is appropriately made in a greater part of a desired band, as shown in FIG. 19, a defective condition is produced only in the vicinity of an end of the band, as shown in FIGS. 20 and 21.

Under the circumstances, cause investigation was performed with a suspicion that there was a cause other than circuit design. As a result, it was experimentally confirmed that, when a modulation wave was input to a single GaN HEMT while power supply-side impedance and load impedance were set at ones equivalent to those in an amplifier module, a large amplitude shift and a large phase shift occurred as the input power level became relatively high.

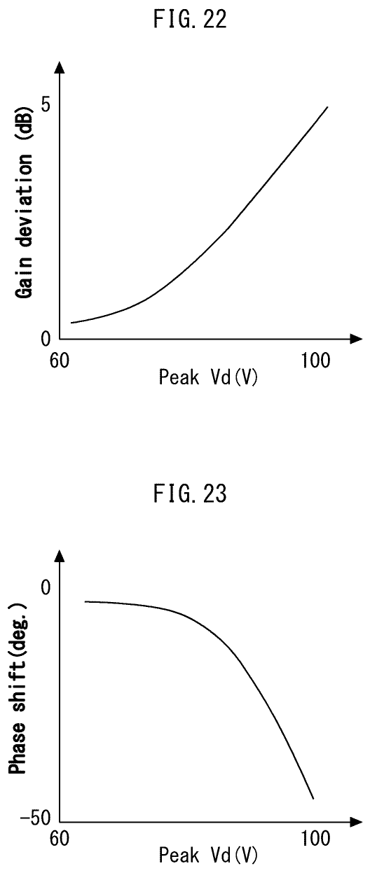

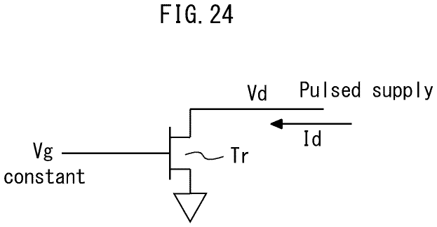

FIG. 22 is a graph showing a result of simulating an AM-AM shift amount with respect to a peak value of a drain voltage of a single GaN HEMT. FIG. 23 is a graph showing a result of simulating an AM-PM shift amount with respect to the peak value of the drain voltage of the single GaN HEMT. It was confirmed from analysis of the simulation that the shift amounts depended strongly on the peak value of the drain voltage. The inventors inferred from this that a transient response delay of a drain current after application of a stress voltage pulse, which was a phenomenon often observed at a frequency at an end of a band by a GaN HEMT, occurred notably.

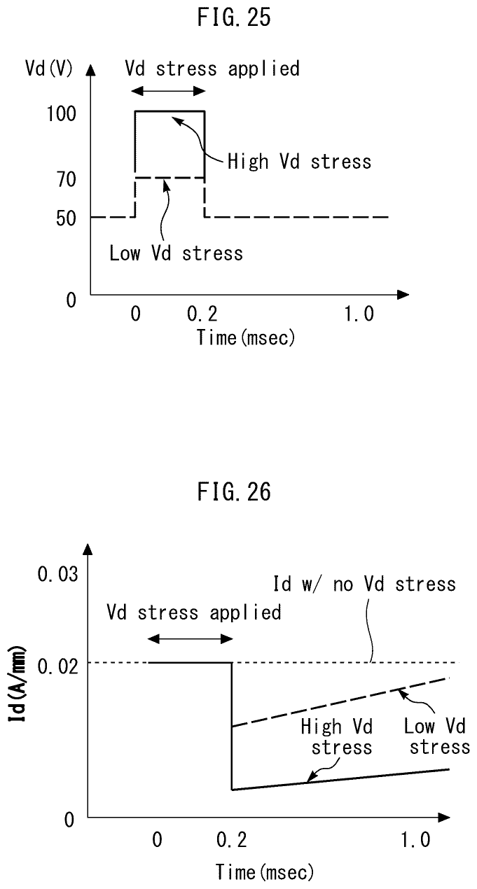

An example of a transient response delay of a drain current will be described below. FIG. 24 is a diagram showing an example of a setup for measuring a transient response delay of a drain current after application of a stress voltage pulse. A gate voltage Vg is set such that a given drain current Id flows. A drain voltage Vd is temporarily raised from a given level, e.g., a power supply voltage of an amplifier Tr, to a higher voltage in terms of pulses and then returned to the original voltage. FIG. 25 is a graph showing a drain voltage waveform at the time of stress voltage pulse application. FIG. 26 is a graph showing a transient response waveform of the drain current corresponding to FIG. 25. As shown in FIGS. 25 and 26, it can be seen that the drain current rises relatively early immediately after low drain voltage stress and that the drain current rises late immediately after high drain voltage stress.

A drain voltage of a GaN HEMT at the time of simultaneous amplification of many subcarriers subjected to multilevel modulation sometimes has a very high peak output, as described earlier. It is inferred that, if a transient response of a drain current is delayed at this time, the drain current does not rise, a gain becomes low at low input power, as shown in FIGS. 20 and 21, and a phase change within a dynamic range becomes large simultaneously. In other words, it is inferred that there is an AM-AM or AM-PM shift which cannot be compensated for by a Digital Pre-distorter DPD due to a too high peak output voltage. It was thus inferred that the cause of a defective condition which interfered with distortion compensation by the Digital Pre-distorter DPD was a memory effect due to a transient response of a drain current.

The challenge is to suppress changes in AM-AM/AM-PM to the degree that distortion compensation by a Digital Pre-distorter DPD functions appropriately. It is thus conceivable to place, in front of a power amplifier module, the diode linearizer shown in FIG. 2 capable of compensating for AM-AM/AM-PM with a simple circuit configuration. The inventors have experimentally confirmed that suppression of an AM-PM shift was especially important in appropriately making distortion compensation by the Digital Pre-distorter DPD.

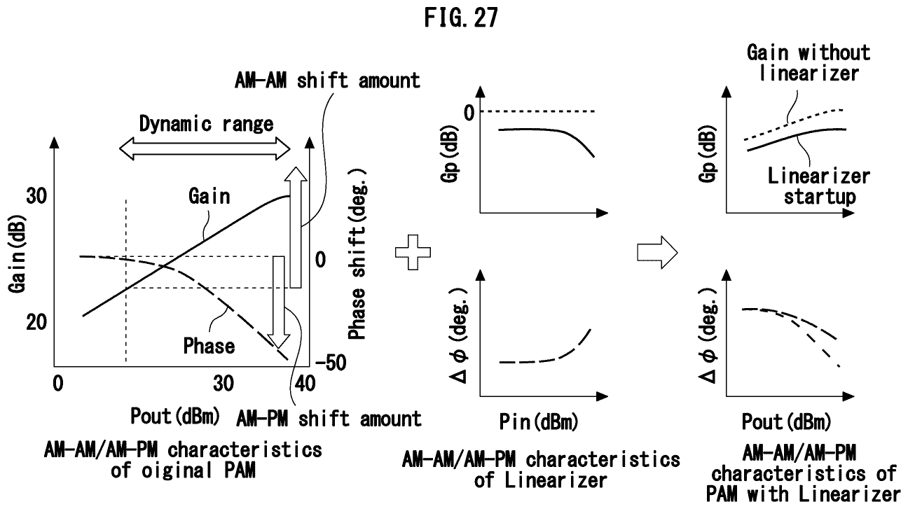

FIG. 27 is a chart for explaining influence of placing a linearizer in front on AM-AM/AM-PM. It can be seen that changes in AM-AM/AM-PM are suppressed by compensation by the linearizer. Thus, in a power amplifier, in front of which a diode linearizer LNZ is placed, distortion compensation by a Digital Pre-distorter DPD acts appropriately, and implementation of the characteristics shown in FIG. 19 can be expected in the whole desired band.

However, it is found from characteristics of a PAM with the linearizer in FIG. 27 that the PAM suffers the problem of reduction in gain (linear gain) of an amplifier when output power Pout is low. If the power amplifier is considered as a product, a gain of the product changes depending on the presence or absence of activation of the diode linearizer LNZ to become a problem. Depending on the amounts of compensation of AM-AM/AM-PM by the diode linearizer LNZ, a gain difference of about 2 to 3 dB is produced.

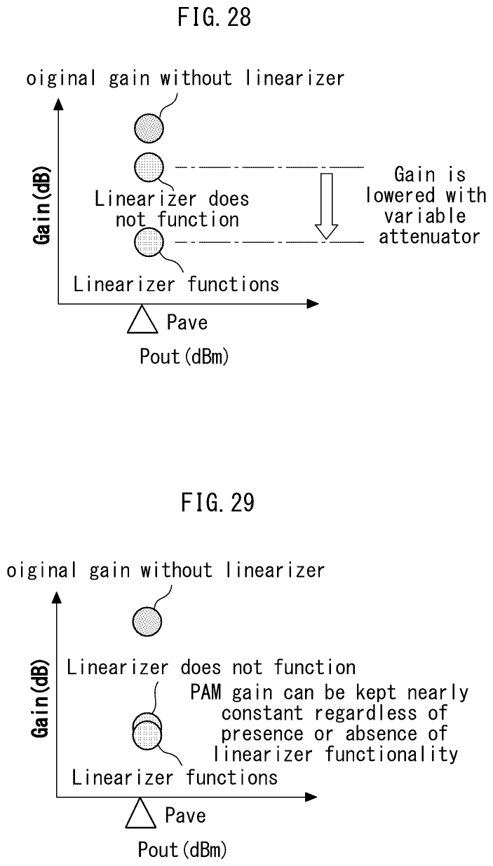

In the present embodiment, the variable attenuator VATT is mounted in the power amplifier to suppress the above-described gain difference. FIG. 28 is a chart showing a gain in the absence of the variable attenuator. In the absence of the variable attenuator VATT, there is a large gain deviation between presence and absence of activation of the diode linearizer LNZ. FIG. 29 is a chart showing a gain in the presence of the variable attenuator. A gain is higher in a case where the diode linearizer LNZ is not activated than in a case where the diode linearizer LNZ is activated. For this reason, the attenuation amount of the variable attenuator VATT is increased when the diode linearizer LNZ is not activated. This makes it possible to make a gain constant regardless of the presence or absence of activation of the diode linearizer LNZ.

As has been described above, in the present embodiment, a diode linearizer and a variable attenuator are connected in series to the input of an amplifier, and if a peak value of a drain voltage of the amplifier exceeds a threshold, the diode linearizer is made to function. For this reason, even if a Digital Pre-distorter cannot make distortion compensation well due to a memory effect arising from a momentary drain voltage of the amplifier, the linearizer can suppress deterioration of linearity. Thus, a distortion characteristic which is generally required of a base station can be achieved by distortion compensation by the Digital Pre-distorter. If the diode linearizer functions, since a gain decreases, an attenuation amount of the variable attenuator is reduced. This allows reduction in gain variation of a power amplifier.

Since the diode linearizer LNZ and the variable attenuator VATT are very simple analog circuits, the diode linearizer LNZ and the variable attenuator VATT can each be implemented not only by a GaN HEMT but also by a GaAs FET/HEMT and are suitable for size reduction and cost reduction. Note that, since the same configuration can be implemented by using a group IV Si-based semiconductor, a power amplifier according to the present embodiment is not limited to group III-V.

In PTL 1 as well, a drain voltage of an FET of a power amplifier is monitored, and a phase shifter compensates for AM-PM in accordance with the monitored drain voltage. However, if implementation using analog circuits is presupposed, AM-AM may change simultaneously with compensation of AM-PM. Thus, the present embodiment that compensates for both the AM-PM and the AM-AM has a larger compensation effect. A gain deviation between presence and absence of activation of the diode linearizer LNZ can also be suppressed.

Note that, although Doherty amplifiers are the mainstream as practical power amplifiers for base stations, a similar phenomenon occurs due to a trapping effect of a transistor itself, and a Digital Pre-distorter may not be able to make distortion compensation for an amplifier other than a Doherty amplifier. The present embodiment is thus effective for a case where an amplifier is not a Doherty amplifier.

### Second Embodiment

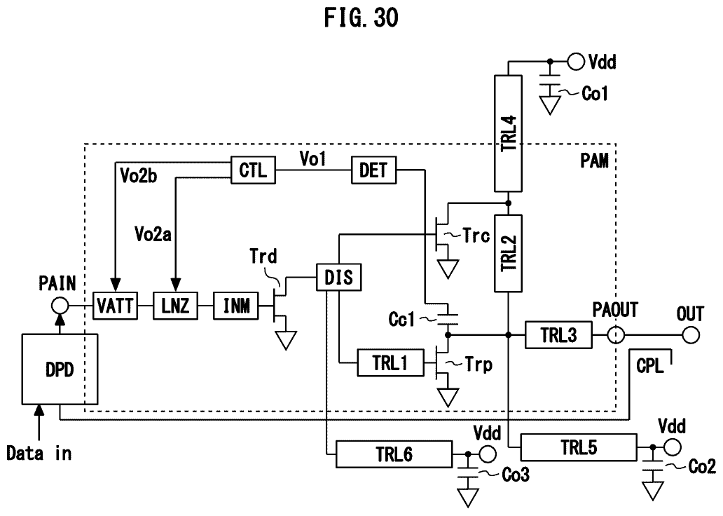

FIG. 30 is a circuit diagram showing a power amplifier according to a second embodiment. While the peak value of the drain voltage of the carrier amplifier Trc of the Doherty amplifier is detected in the first embodiment, a peak value of a drain voltage of a peak amplifier Trp is detected in the present embodiment. Other components are the same as those in the first embodiment. In this case as well, the same effects as those of the first embodiment can be obtained.

### Third Embodiment

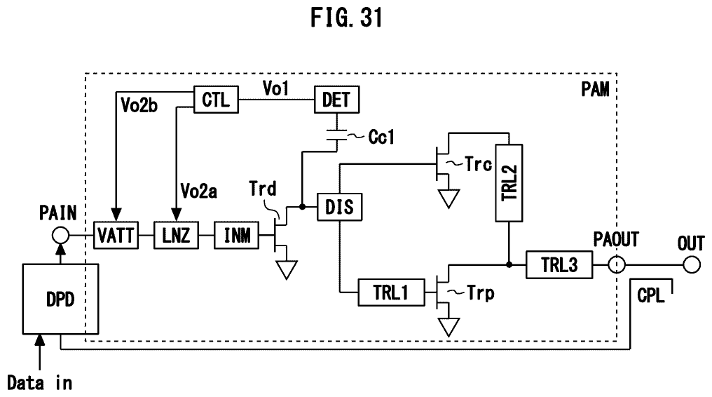

FIG. 31 is a circuit diagram showing a power amplifier according to a third embodiment. While the peak value of the drain voltage of the carrier amplifier Trc of the Doherty amplifier is detected in the first embodiment, a peak value of a drain voltage of a driver amplifier Trd is detected in the present embodiment. Other components are the same as those of the first embodiment.

Generally, a peak value of a drain voltage of a carrier amplifier Trc at a final stage is higher than the peak value of the drain voltage of the driver amplifier Trd. Note that, depending on the circuit design, a peak value of a drain voltage of a GaN HEMT in the driver amplifier Trd may become excessively high to become a major factor for a transient response characteristic delay of a drain current. In this case, the present embodiment is effective, and the same effects as those of the first embodiment can be obtained.

Note that although only one driver amplifier Trd is provided in FIG. 31, one driver amplifier Trd may be provided for the carrier amplifier Trc, and one driver amplifier Trd may be provided for the peak amplifier Trp. In this case, the same effects as those of the first embodiment can be obtained by monitoring a drain voltage of the driver amplifier Trd on the carrier amplifier Trc side.

### Fourth Embodiment

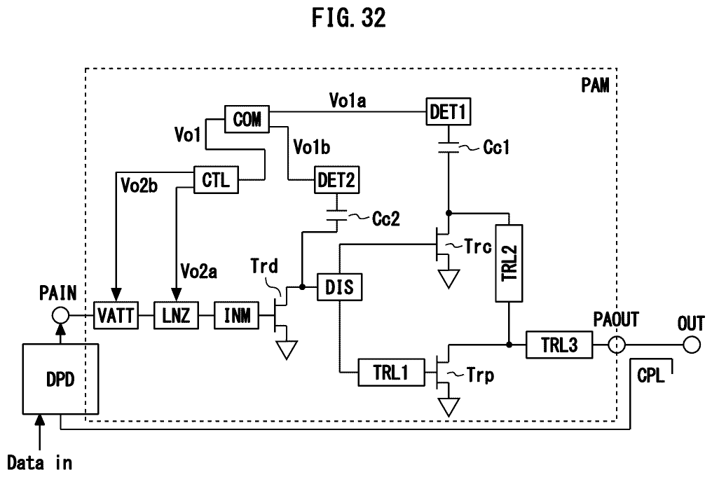

FIG. 32 is a circuit diagram showing a power amplifier according to a fourth embodiment. In the present embodiment, a peak detector DET1 detects a peak value of a drain voltage of a carrier amplifier Trc in a Doherty amplifier, and a peak detector DET2 detects a peak value of a drain voltage of a driver amplifier Trd. A comparator COM selects a higher one of the voltages to provide the voltage to a controller CTL. The controller CTL applies control voltages to a diode linearizer LNZ and a variable attenuator VATT in accordance with an output signal from the comparator COM. Other components are the same as those of the first embodiment, and the same effects as those of the first embodiment can be obtained.

### REFERENCE SIGNS LIST

CTL controller
CPL directional coupler
DET, DET1, DET2 peak detector
DPD Digital Pre-distorter
LNZ diode linearizer
Trc carrier amplifier
Trd driver amplifier
Trp peak amplifier
VATT variable attenuator

1. A power amplifier comprising:
an amplifier using a GaN HEMT;
a diode linearizer and a variable attenuator which are connected in series to an input of the amplifier;
a peak detector detecting a peak value of a drain voltage of the amplifier; and
a controller making the diode linearizer function as a linearizer to reduce an attenuation amount of the variable attenuator if the peak value exceeds a threshold.

2. The power amplifier according to claim 1, wherein the controller controls the diode linearizer so as to change a gain and a phase of a signal which passes through the diode linearizer if the peak value exceeds a threshold and so as not to change a gain and a phase of a signal which passes through the diode linearizer if the peak value does not exceed the threshold, and
the controller controls the variable attenuator such that an attenuation amount of a signal which passes through the variable attenuator if the peak value exceeds a threshold is smaller than an attenuation amount of a signal which passes through the variable attenuator if the peak value does not exceed the threshold.

3. The power amplifier according to claim 1, comprising a directional coupler connected to an output of the amplifier, and a digital pre-distorter monitoring an output signal from the amplifier with the directional coupler and providing an inverse of a component which is to be distorted by the amplifier to the amplifier in advance.

4. The power amplifier according to claim 1, wherein the amplifier includes a Doherty amplifier.

5. The power amplifier according to claim 4, wherein the Doherty amplifier includes a carrier amplifier and a peak amplifier which are connected in parallel to each other, and the peak detector detects a peak value of a drain voltage of the carrier amplifier.

6. The power amplifier according to claim 4, wherein the Doherty amplifier includes a carrier amplifier and a peak amplifier which are connected in parallel to each other, and the peak detector detects a peak value of a drain voltage of the peak amplifier.

7. The power amplifier according to claim 4, wherein the amplifier includes a driver amplifier connected to an input of the Doherty amplifier, and the peak detector detects a peak value of a drain voltage of the driver amplifier.

8. The power amplifier according to claim 4, wherein the Doherty amplifier includes a carrier amplifier and a peak amplifier which are connected in parallel to each other,
the amplifier includes a driver amplifier connected to an input of the Doherty amplifier, and
the peak detector detects a peak value of a drain voltage of the carrier amplifier and a peak value of a drain voltage of the driver amplifier and selects a higher one of the voltages to provide the voltage to the controller.
